(19) United States
(12) Patent Application Publication
(10) Pub. No.: US 2026/0271244 A1
(43) Pub. Date: Sep. 10, 2026

(54) Cooling System of Cabinet and the Method of Cooling the Cabinet

(71) Applicant: HOLTHRONE CO., LTD., TAICHUNG (TW)

(72) Inventors: CHEN YUAN LAI, TAICHUNG (TW); WEI PING LI, TAICHUNG (TW)

(21) Appl. No.: 19/555,294

(22) Filed: Mar. 3, 2026

(30) Foreign Application Priority Data
Mar. 5, 2025 (TW) 114108113

(51) Int. Cl. H05K 7/20

(52) U.S. Cl. CPC H05K 7/20818; H05K 7/20836

(57) ABSTRACT

A cooling system comprises a storage tank, a cabinet, a main pipe, a pond, a circulating pipe and a control unit. The storage tank stores liquefied gas. The main pipe is connected to the storage tank and the cabinet to deliver a cooling gas, which is vaporized from the liquefied gas, to the cabinet. The circulating pipe has opposite ends connected to the cabinet. A pump is provided in the circulating pipe to suck the cooling gas in the cabinet into the circulating pipe, and the cooling gas flows back to the cabinet. The pond receives cooling liquid, and both the main pipe and the circulating pipe has a section sinking in the cooling liquid of the pond. The control unit controls the main pipe, the circulating pipe and the pump to be opened or closed according to environment parameters in the cabinet.

### BACKGROUND OF THE INVENTION

The present invention relates to a cooling system for servers, and more particularly to an energy-efficient cooling system of a cabinet and a method of cooling a cabinet.

Due to their superior space utilization, rack servers have become the mainstream configuration for server installations in recent years. A plurality of rack servers can be installed within a cabinet for centralized management. The design of such cabinets is specifically optimized to accommodate the servers while minimizing the overall size.

In recent years, as the computing speeds of servers continue to escalate, their power consumption has increased correspondingly, thereby generating substantial thermal loads. For the rack servers and cabinets characterized by high spatial density, the challenge of heat dissipation of the cabinet during working has become increasingly prominent. Consequently, it is necessary to implement cooling systems to reduce the servers’ temperatures and ensure optimal working performance.

Conventional cabinet cooling systems primarily consist of two types: air-cooling type and liquid-cooling type, both of which possess distinct advantages and disadvantages. High energy consumption, however, remains a common problem for both systems. It is easy to understanding, it needs a large pump to drive larger volumes of gas or fluid for heat exchange that may generate a high cooling capacity. Therefore, both air-cooling and liquid-cooling systems need significant energy to achieve the desired cooling performance.

### SUMMARY OF THE INVENTION

In view of the above, the primary object of the present invention is to provide a cooling system to generate a desired cooling performance to a cabinet with lower energy consumption, and a method of cooling the cabinet with the cooling system.

In order to achieve the objective of the present invention, the present invention discloses that a cooling system comprises a storage tank, a cabinet, a sensor, a main pipe, a pond, a circulating pipe and a control unit. The storage tank stores liquefied gas. The cabinet has a space therein, and the sensor senses parameters in the space of the cabinet. The main pipe has opposite ends connected to the storage tank and the cabinet. The liquefied gas is vaporized into cooling gas in the main pipe and then is delivered to the space of the cabinet. The main pipe is provided with a main valve to open or close the main pipe. The pond receives cooling liquid, and the main pipe has a section sinking in the cooling liquid of the pond. The circulating pipe has an inlet and an outlet, both of which are connected to the cabinet. A pump is provided in the circulating pipe to suck the cooling gas in the cabinet into the circulating pipe via the inlet, and the cooling gas flows back to the cabinet via the outlet. The circulating pipe has a section sinking in the cooling liquid of the pond. The circulating pipe is provided with a circulating valve to open or close the circulating pipe. The control unit controls the main valve, the circulating pipe and the pump according to the parameters sensed by the sensor.

In an embodiment, the cooling system further comprises a vaporizer provided to the main pipe to vaporize the liquefied gas into cooling gas.

In an embodiment, the vaporizer is between the pond and the cabinet.

In an embodiment, the cooling system further comprises an exhausting pipe connected to the cabinet to exhaust the cooling gas in the cabinet out, wherein the exhausting pipe is provided with an exhausting valve to open or close the exhausting pipe.

In an embodiment, the exhausting pipe is connected to the circulating pipe via a 3-way valve, so that the pump is opened to exhaust the cooling gas out of the cabinet via the exhausting pipe.

In an embodiment, the sensor has two flowmeters provided in the main pipe and the exhausting pipe respectively.

In an embodiment, the control unit opens or closes the exhausting valve according to the parameters sensed by the sensor.

In an embodiment, the cabinet is provided with a fan in the space.

The present invention further provides a method of cooling a cabinet, and the method comprises the following steps:

Charging step: delivering liquefied gas in a storage tank to a main pipe, vaporizing the liquefied gas into cooling gas in the main pipe, and then delivering the cooling gas into a space of a cabinet via the main pipe, wherein the main pipe has a section sinking in cooling liquid of a pond, and the charging step is stopped when a predetermined mount of the cooling gas is delivered to the cabinet.

Circulating step: sucking the cooling gas in the cabinet into a circulating pipe and delivering the cooling gas back to the cabinet via the circulating pipe, wherein the circulating pipe has a section sinking in the cooling liquid of the pond when a temperature in the space of the cabinet is equal to or higher than a working temperature.

Filling step: stopping the circulating step when the temperature in the space of the cabinet is equal to or higher than a warning temperature, and then delivering the liquefied gas to the main pipe, vaporizing the liquefied gas into the cooling gas in the main pipe, and then delivering the cooling gas to the space of the cabinet until the temperature in the space of the cabinet equal to or lower than a reset temperature, wherein the warning temperature is higher than the working temperature and the reset temperature is lower than the warning temperature.

In an embodiment, the method further comprises the following step before the charging step:

Preliminary step: removing air in the space of the cabinet out until a pressure in the space equal to or lower than a preparation pressure.

In an embodiment, air in the main pipe and the circulating pipe is removed as well in the preliminary step.

In an embodiment, the method further comprises the following step after the filling step:

Exhausting step: exhausting a predetermined quantity of the cooling gas out of the cabinet.

In an embodiment, a quantity of the cooling gas delivered to the cabinet in the filling step is recorded, and a quantity of the cooling gas exhausted out of the cabinet in the exhausting step is monitored, and the exhausting step is stopped when the quantity of the cooling gas delivered to the cabinet in the filling step is equal to the quantity of the cooling gas exhausted out of the cabinet in the exhausting step.

In an embodiment, the reset temperature is lower than the working temperature.

In an embodiment, the filling step and the exhausting step are performed at the same time.

A preferred embodiment is described hereafter, accompanied with drawings, according to the objective and function of the present invention.

### BRIEF DESCRIPTION OF DRAWINGS

FIG. 1 is a diagrammatic view of the cooling system of a preferred embodiment of the present invention;

FIG. 2 is a diagrammatic view of the cooling system of a preferred embodiment of the present invention, showing the preliminary step of the cooling method;

FIG. 3 is a diagrammatic view of the cooling system of a preferred embodiment of the present invention, showing the charging step of the cooling method;

FIG. 4 is a diagrammatic view of the cooling system of a preferred embodiment of the present invention, showing the circulating step of the cooling method;

FIG. 5 is a diagrammatic view of the cooling system of a preferred embodiment of the present invention, showing the filling step of the cooling method; and

FIG. 6 is a diagrammatic view of the cooling system of a preferred embodiment of the present invention, showing the exhausting step of the cooling method.

### DETAILED DESCRIPTION OF THE INVENTION

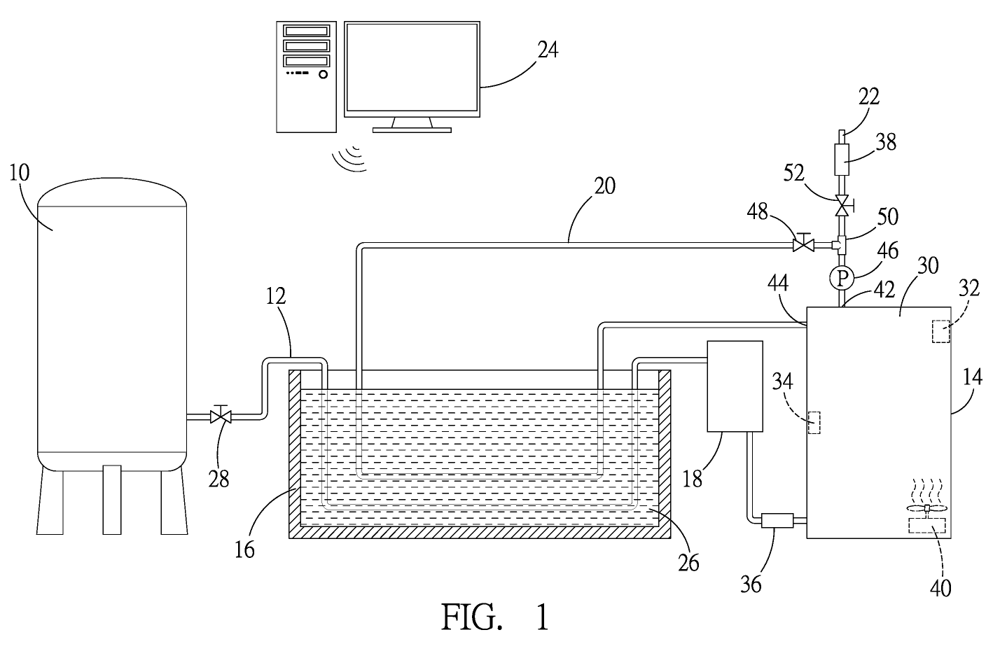

As shown in FIG. 1, a cooling system of the preferred embodiment of the present invention includes a storage tank 10, a main pipe 12, a cabinet 14, a pond 16, a vaporizer 18, a sensor, a circulating pipe 20, an exhausting pipe 22, and a control unit 24.

The storage tank 10 stores liquefied gas (not shown), which is liquid nitrogen in the present embodiment. The main pipe 12 has an end connected to the storage tank and the other end connected to the cabinet 14. The pond 16 receives cooling liquid 26, which is water in the present embodiment. The main pipe 12 has at least a section sinking in the cooling liquid 26 to create a heat exchange between the liquefied gas in the main pipe 12 and the cooling liquid 26 to cool the cooling liquid 26. A main valve 28 is mounted on the main pipe 12 between the storage tank 12 and the pond 16 to open or close the main pipe 12. The vaporizer 18 is connected to the main pipe 12 between the cooling pond 16 and the cabinet 14 to vaporize the liquefied gas (liquid nitrogen) into cooling gas (nitrogen gas). The end of the main pipe 12 connected to the cabinet 14 closed to a bottom of the cabinet 14.

The cabinet 14 has a space 30 to store servers (not shown) therein. The sensor is used to sense environment parameters in the space 30, such as temperature, pressure, and humidity. In the present embodiment, the sensor includes a thermometer 32 and a pressure gauge 34 mounted in the space 30 of the cabinet 14 to monitor temperature and pressure in the cabinet 14. The sensor further includes two flowmeters 36 and 38 on the main pipe 12 and the exhausting pipe 22 respectively to monitor a quantity of the cooling gas flowing into the cabinet 14 via the main pipe 12 and a quantity of the cooling gas flowing out of the cabinet 14 via the exhausting pipe 22. A fan 40 is mounted in the cabinet 14 to generate a circulation of the cooling gas in the cabinet 14.

The circulating pipe 20 has an inlet 42 and an outlet 44, both of which are connected to the cabinet 14. A pump 46 is provided in the circulating pipe 20 adjacent to the inlet 42 to suck the cooling gas in the cabinet 14 into the circulating pipe 20 via the inlet 42, and the cooling gas flows back to the cabinet 14 via the outlet 44. The circulating pipe 20 has a section sinking in the cooling liquid 26 of the pond 16, thereby the cooling gas in the circulating pipe 20 will be cooled by the cooling liquid 26 when it flows through the section of the circulating pipe 20 sinking in the cooling liquid 26 of the pond 16. A circulating valve 48 is mounted on the circulating pipe 20 to open or close the circulating pipe 20.

The exhausting pipe 22 is connected to a top of the cabinet 14 to exhaust the cooling gas out of the cabinet 14. In the present embodiment, the exhausting pipe 22 is connected to the circulating pipe 20 through a 3-way valve 50. An exhausting valve 52 is mounted on the exhausting pipe 22 to be operated to open or close the exhausting pipe 22. The cooling gas will circulate in the circulating pipe 20 when the circulating valve 48 is opened, the exhausting valve 52 is closed, and the pump 46 is turned on. The cooling gas in the cabinet 14 and in the circulating pipe 20 will be exhausted out via the exhausting pipe 22 when the circulating valve 48 and the exhausting valve 52 are closed, and the pump 46 is turned off.

The main valve 28, the exhausting valve 52, the circulating valve 48, the pump 46 and the sensor (the thermometer 32, the pressure gauge 34 and the flowmeters 36, 38) are connected to the control unit 24. The control unit 24 receives data from the sensor to open or close the main valve 28, the exhausting valve 52, the circulating valve 48 and the pump 46 accordingly.

According to the cooling system as described above, a method of cooling the cabinet 14 of the preferred embodiment of the present invention includes the following steps:

### Preliminary step

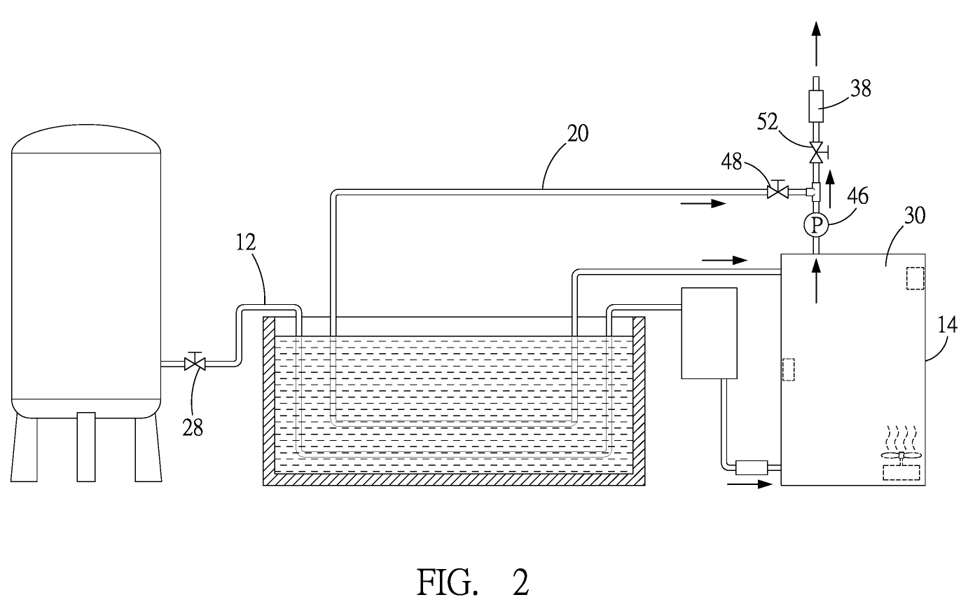

As shown in FIG. 2, before the cooling system works, a plurality of servers (not shown) are mounted in the space 30 of the cabinet 14, and then close the main valve 28, open the circulating valve 48 and the exhausting valve 52 and turn on the pump 46 to evacuate air, moisture, dust, particles in the space 30 of the cabinet 14, the main pipe 12 and the circulating pipe 20 out via the exhausting pipe 22. The control unit 24 closes the exhausting valve 52 and turns the pump 46 off when a pressure sensed by the pressure gauge 34 is lower than a preparation pressure. In the present embodiment, the preparation pressure is between 0.05 atm and 0.1atm. Now the space 30 of the cabinet 14, the main pipe 12 and the circulating pipe 20 are almost vacuum since most of the air, moisture, dust and particles are evacuated. In another embodiment, the control unit 24 closes the exhausting valve 52 and turns the pump 46 off according to the flowmeters 36, 38 since the quantity of air being evacuated may be calculated by the sizes of the cabinet 14, the main pipe 12 and the circulating pipe 20.

### Charging step

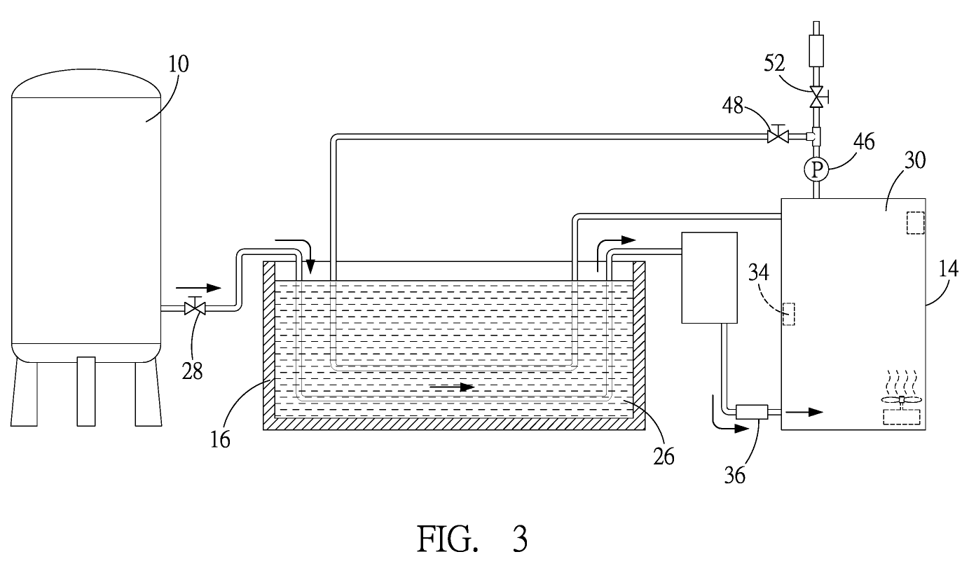

As shown in FIG. 3, close the circulating valve 48 (the exhausting valve 52 is kept closed), and then open the main valve 28 to let the liquefied gas in the storage tank 10 entering the main pipe 12, and then vaporize the liquefied gas into the cooling gas by the vaporizer 18 after flowing through the section of the main pipe 12 sinking in the cooling liquid 26 of the pond 16, and finally flowing into the space 30 of the cabinet 14. The control unit 24 closes the main valve 28 when the space 30 of the cabinet 14 is filled with a predetermined quantity of the cooling gas. In the present embodiment, the control unit 24 closes the main valve 28 once a pressure in the cabinet 14 reaches a preset pressure. In an embodiment, the preset pressure is set in a range between 0.95atm and 1.1atm. In another embodiment, the main valve 28 is closed according to a quantity of the cooling gas flowing into the cabinet 14. The flowmeter 36 in the main pipe 12 serves the function of monitoring the quantity of the cooling gas flowing into the cabinet 14. Now, the cabinet 14 is charged with sufficient cooling gas, and the servers may be turned on to work.

### Circulating step

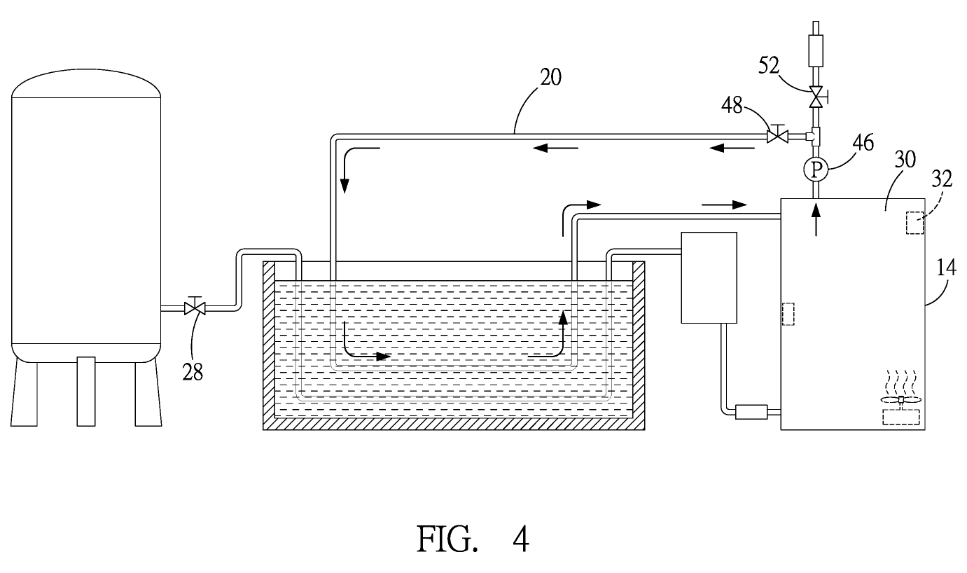

As shown in FIG. 4, a temperature in the cabinet 14 will rise because the servers are working, and the control unit 24 will open the circulating valve 48 and the pump 46 (the main valve 28 and the exhausting valve 52 are closed) when the thermometer 32 senses the temperature equal to or higher than a working temperature. At this time, the cooling gas in the cabinet 14 will be sucked into the circulating pipe 20 via the inlet 42 and cooled by the liquid 26 in the pond 16, and then flows back to the cabinet via the outlet 44 to decrease the temperature in the cabinet 14. In the present embodiment, the working temperature is in a range between 45℃ and 50℃.

It is noted that the inlet 42 of the circulating pipe 20 is close to the top of the cabinet 14 to suck the warmer cooling gas in the cabinet 14 into the circulating pipe 20 that may keep the space 30 of the cabinet 14 having a consistent temperature.

### Filling step

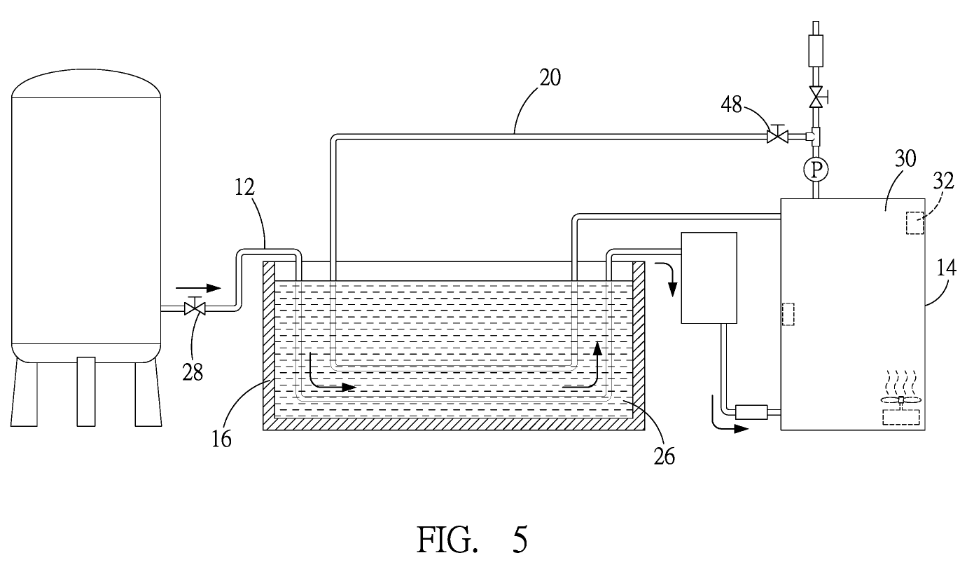

As shown in FIG. 5, the temperature in the cabinet 14 will rise as long as the servers keeps working even through the circulating step keeps cooling the cooling gas. The filling step starts when the sensor (thermometer 32) senses the temperature in the cabinet 14 higher than or equal to a warning temperature. The control unit 24 closes the circulating valve 48 and opens the main valve 20 to let the liquefied gas in the storage tank 10 entering the main pipe 12 again, and then the liquefied gas is vaporized into the cooling gas by the vaporizer 18 after flows through the section of the main pipe 12 sinking in the cooling liquid 26 of the pond 16, and finally flows to the space 30 of the cabinet 14. The temperature in the cabinet 14 will drops because of the new cooling gas. The filling step is stopped (close the main valve 20) when the sensor (thermometer 32) senses the temperature in the cabinet 14 lower than or equal to a reset temperature. In the present embodiment, the warning temperature is in a range between 60℃ and 70℃, and the reset temperature is in a range between 25℃ and 28℃.

### Exhausting step

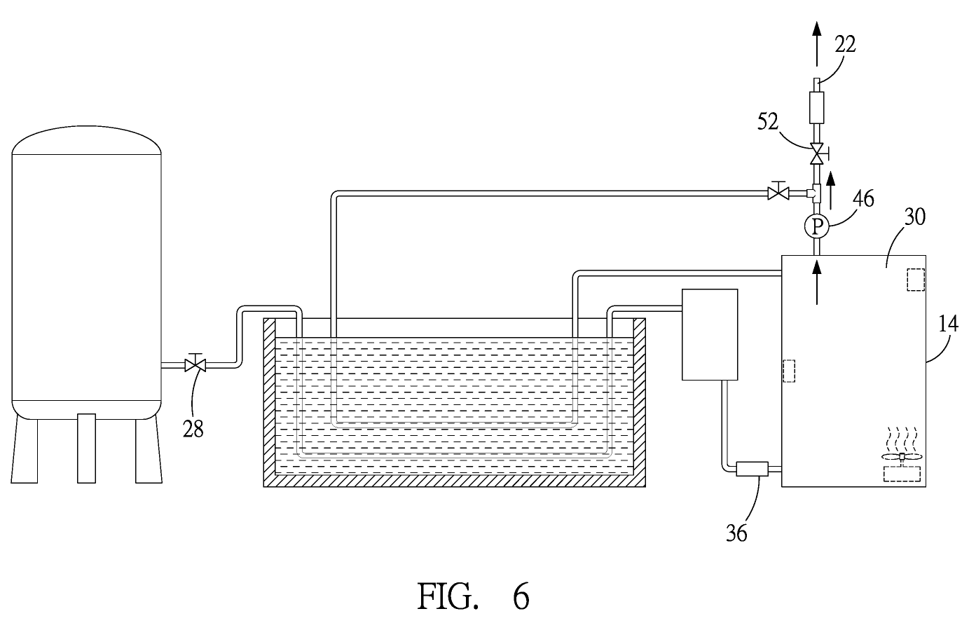

It is easy to understand that a total quantity of the cooling gas in the cabinet increases after the filling step. The exhausting step removes the excess cooling gas to keep a proper quantity of the cooling gas in the cabinet 14. As shown in FIG. 6, the exhausting step includes opening the pump 46 and the exhausting valve 53 to exhaust the cooling gas out of the cabinet 14 via the exhausting pipe 22. In the present embodiment, the flowmeter 36 in the main pipe 12 records a quantity of the cooling gas into the cabinet 14 in the filling step, and the flowmeter 38 in the exhausting pipe 22 records a quantity of the cooling gas out of the cabinet 14 in the exhausting step. The exhausting step stops when the quantity of the cooling gas entering the cabinet 14 equals the quantity exiting. In an embodiment, the filling step and the exhausting step are performed at the same time.

With the system and method as described above, the present invention provides the pond 16 filled with cooling liquid 26 to store the unused cooling power of the liquefied gas, and supplies these unused cooling power via the circulating pipe 20 to provide a high-efficient cooling capacity.

It must be pointed out that the embodiments described above are only some preferred embodiments of the present invention. All equivalent structures which employ the concepts disclosed in this specification and the appended claims should fall within the scope of the present invention.

1. A cooling system, comprising:
a storage tank storing liquefied gas;
a cabinet having a space therein;
a sensor sensing parameters in the space of the cabinet;
a main pipe having opposite ends connected to the storage tank and the cabinet, wherein the liquefied gas is vaporized into cooling gas in the main pipe and then is delivered to the space of the cabinet; and the main pipe is provided with a main valve to open or close the main pipe;
a pond receiving cooling liquid, wherein the main pipe has a section sinking in the cooling liquid of the pond;
a circulating pipe having an inlet and an outlet, both of which are connected to the cabinet, wherein a pump is provided in the circulating pipe to suck the cooling gas in the cabinet into the circulating pipe via the inlet, and the cooling gas flows back to the cabinet via the outlet; the circulating pipe has a section sinking in the cooling liquid of the pond; and the circulating pipe is provided with a circulating valve to open or close the circulating pipe; and
a control unit controlling the main valve, the circulating pipe and the pump to be opened or closed according to the parameters sensed by the sensor.

2. The cooling system of claim 1, further comprising a vaporizer provided to the main pipe to vaporize the liquefied gas into cooling gas.

3. The cooling system of claim 2, wherein the vaporizer is between the pond and the cabinet.

4. The cooling system of claim 1, further comprising an exhausting pipe, which has an end connected to the cabinet, to exhaust the cooling gas out of the cabinet, wherein the exhausting pipe is provided with an exhausting valve to open or close the exhausting pipe.

5. The cooling system of claim 4, wherein the exhausting pipe is connected to the circulating pipe via a 3-way valve, so that the pump is opened to exhaust the cooling gas out of the cabinet via the exhausting pipe.

6. The cooling system of claim 4, wherein the sensor has two flowmeters provided in the main pipe and the exhausting pipe respectively.

7. The cooling system of claim 4, wherein the control unit opens or closes the exhausting valve according to the parameters sensed by the sensor.

8. The cooling system of claim 1, wherein the cabinet is provided with a fan in the space.

9. A method of cooling a cabinet, comprising the steps of:
charging step: delivering liquefied gas to a main pipe, vaporizing the liquefied gas into cooling gas in the main pipe, and then delivering the cooling gas into a space of a cabinet via the main pipe, wherein the main pipe has a section sinking in cooling liquid of a pond, and the charging step is stopped when a predetermined quantity of the cooling gas is delivered to the cabinet;
circulating step: delivering the cooling gas in the cabinet into a circulating pipe and delivering the cooling gas back to the cabinet via the circulating pipe when a temperature in the space of the cabinet is equal to or higher than a working temperature, wherein the circulating pipe has a section sinking in the cooling liquid of the pond; and
filling step: stopping the circulating step when the temperature in the space of the cabinet is equal to or higher than a warning temperature, and then delivering the liquefied gas to the main pipe, vaporizing the liquefied gas into the cooling gas in the main pipe, and then delivering the cooling gas to the space of the cabinet via the main pipe until the temperature in the space of the cabinet equal to or lower than a reset temperature, wherein the warning temperature is higher than the working temperature and the reset temperature is lower than the warning temperature.

10. The method of claim 9, further comprising the step before the charging step:
preliminary step: removing air in the space of the cabinet out until a pressure in the space equal to or lower than a preparation pressure.

11. The method of claim 10, wherein air in the main pipe and the circulating pipe is removed as well in the preliminary step.

12. The method of claim 9, further comprising the step after the filling step:
exhausting step: exhausting a predetermined quantity of the cooling gas out of the cabinet.

13. The method of claim 12, wherein a quantity of the cooling gas delivered to the cabinet in the filling step is recorded, and a quantity of the cooling gas exhausted out of the cabinet in the exhausting step is monitored, and the exhausting step is stopped when the quantity of the cooling gas exhausted out of the cabinet in the exhausting step is equal to the quantity of the cooling gas delivered to the cabinet in the filling step.

14. The method of claim 9, wherein the reset temperature is lower than the working temperature.

15. The method of claim 12, wherein the filling step and the exhausting step are performed at the same time.
